(19) United States
(12) Patent Application Publication
(10) Pub. No.: US 2018/0331273 A1
(43) Pub. Date: Nov. 15, 2018

(54) ELECTROMOTIVE FILM FOR THERMOELECTRIC CONVERSION ELEMENT, AND THERMOELECTRIC CONVERSION ELEMENT

(71) Applicant: NEC CORPORATION, Tokyo (JP)

(72) Inventors: Akihiro KIRIHARA, Tokyo (JP); Masahiko ISHIDA, Tokyo (JP); Kazuki IHARA, Tokyo (JP); Yuma IWASAKI, Tokyo (JP); Hiroko SOMEYA, Tokyo (JP)

(73) Assignee: NEC CORPORATION, Tokyo (JP)

(21) Appl. No.: 15/774,177

(22) PCT Filed: Nov. 9, 2016
(86) PCT No.: PCT/JP2016/083157

§ 371 Date: May 7, 2018

(30) Foreign Application Priority Data
Nov. 13, 2015 (JP) 2015-223201
Aug. 19, 2016 (JP) 2016-161325

(51) Int. Cl. H01L 37/04

(52) U.S. Cl. CPC H01L 37/04

(57) ABSTRACT

The purpose of the present invention is to provide a thermoelectric conversion element capable of achieving high-efficiency thermoelectric conversion using comparatively inexpensive materials. The present invention is accordingly provided with: a magnetic body layer, an electromotive film for generating electromotive force, and two terminal parts formed so that each is in contact with the electromotive film at two locations having different potentials due to the electromotive force. The electromotive film is formed on the magnetic body layer, said film comprising a Ni-containing magnetic alloy. Said film is doped with a 5d transition metal element, and Ni is the matrix.

### TECHNICAL FIELD

The present invention relates to an electromotive film for a thermoelectric conversion element and a thermoelectric conversion element, and more particularly, to an electromotive film for a thermoelectric conversion element and a thermoelectric conversion element based on a spin Seebeck effect and an anomalous Nernst effect.

### BACKGROUND ART

As one of heat management technologies aimed at a sustainable society, expectations are running high for a thermoelectric conversion element. Heat, such as body heat, solar heat, engine, and industrial exhaust heat, is the most typical energy source that can be collected at various scenes. Thus, thermoelectric conversion is expected to be more and more important in the future in various uses such as enhanced efficiency of energy use, electric supply to a ubiquitous terminal, a sensor, or the like, and visualization of heat flow by heat flow sensing.

In such a situation, a thermoelectric conversion element based on a “spin Seebeck effect (SSE)” that generates a flow of a spin angular momentum (spin current) by creating a temperature gradient (temperature difference) in a magnetic material has been proposed in recent years (PTL 1, and NPLs 1 to 2). The spin Seebeck effect is a phenomenon in which a spin current is generated by providing a temperature difference for a magnetic body. The thermoelectric conversion element based on the spin Seebeck effect has a two-layer structure including a magnetic insulating layer having magnetization in one direction and an electromotive film having conductivity. A temperature gradient is created in this element in a direction perpendicular to the plane, thereby inducing a flow of a spin angular momentum, called a spin current, in a magnetic insulator by the spin Seebeck effect and injecting the spin current into the electromotive film. Then, the spin current is converted into an electric current in an in-plane direction by an “inverse spin Hall effect” in the electromotive film. The inverse spin Hall effect is a phenomenon in which electromotive force is generated in a direction perpendicular to a spin current. This enables “thermoelectric conversion” for generating electricity from a temperature gradient. Since this configuration uses the magnetic insulator having comparatively small heat conductivity, a temperature difference that is a necessary condition for performing effective thermoelectric conversion can be maintained.

Platinum (Pt) having a great spin Hall effect has been mainly adopted so far as a typical material for spin current-electric current conversion. In PTL 1, for example, single-crystal yttrium iron garnet (YIG) (one kind of garnet ferrite) is used as a magnetic insulator and a platinum (Pt) wire is used as an electromotive film, thereby forming a thermoelectric conversion element and performing thermoelectric conversion.

On the other hand, in addition to the spin Seebeck effect, another kind of a thermoelectric effect called an anomalous Nernst effect (ANE) in magnetic metal having conductivity has been known for a long time. The anomalous Nernst effect is a phenomenon in which a voltage is generated in a direction orthogonal to each of directions of magnetization and a heat flow (direction of cross product) when the heat flow is caused to flow through a magnetized magnetic body. A thermoelectric conversion element based on the anomalous Nernst effect is formed of a magnetic metal layer such as Ni and Fe having magnetization in one direction. When a temperature gradient is created in the magnetic metal layer in the direction perpendicular to the plane, an electric current is driven in an in-plane direction.

In this way, both of the spin Seebeck effect and the anomalous Nernst effect are effects having the same symmetry such that electromotive force in an in-plane direction is induced by a temperature gradient in the direction perpendicular to the plane. Thus, development of a hybrid spin thermoelectric element using these two effects together has been also reported (NPL 3).

Further, in a paragraph [0024] in PTL 2, there is a description about a conductive film that “typically, the conductive film 30 is a metal film. A material of the metal film 30 includes a metal material in which “spin orbit coupling” is large. For example, metal materials, such as Au, Pt, Pd, and Ir, in each of which the spin orbit coupling is relatively large, and the other metal material having the f-orbit, or an alloy material which includes the metal materials are used. Also, a similar effect can be obtained by only doping a material such as Au, Pt, Pd, and Ir into a typical metal film material such as Cu at 0.5 to 10%”.

### CITATION LIST

### Patent Literature

[PTL 1] International Patent Publication No. WO2009/151000
[PTL 2] International Patent Publication No. WO2012/046948

### Non Patent Literature

[NPL 1] Ken-ichi Uchida, Tatsumi Nonaka, Takeru Ota and Eiji Saitoh, “Longitudinal spin-Seebeck effect in sintered polycrystalline (Mn, Zn) Fe₂O₄”, Appl. Phys. Lett. 97, 262504 (2010)
[NPL 2] Akihiro Kirihara, Ken-ichi Uchida, Yosuke Kajiwara, Masahiko Ishida, Yasunobu Nakamura, Takashi Manako, Eiji Saitoh & Shinichi Yorozu, “Spin-current-driven thermoelectric coating” Nature Materials 11, 686 (2012)
[NPL 3] B. F. Miao, S. Y. Huang, D. Qu, and C. L. Chien, “Inverse Spin Hall Effect in a Ferromagnetic Metal”, Phys. Rev. Lett. 111, 066602 (2013)

### SUMMARY OF THE INVENTION

### Technical Problem

However, in a case that a thermoelectric conversion element is formed by using Pt, there is an issue of high material cost. In addition, further enhanced conversion efficiency is required for thermoelectric conversion efficiency. The anomalous Nernst effect also makes a temperature difference difficult to be maintained with a metal material having high heat conductivity as a base. Thus, high performance cannot be expected either.

On the other hand, a device using the spin Seebeck effect and the anomalous Nernst effect together as illustrated in NPL 3 enables high conversion efficiency by adding both of the effects while maintaining a temperature difference in an element by using a magnetic insulator having comparatively low heat conductivity. However, only a limited material such as a permalloy Py being an alloy of Ni and Fe is disclosed as a magnetic metal material in NPL 3. Thus, knowledge and a guideline concerned with a material or the like that enables high-efficiency conversion for design of a hybrid element using both of the effects together have not been sufficiently obtained so far.

In addition, there is an issue that a spin current is difficult to flow from a magnetic body into the inside of a conductive film described in PTL 2, in which Cu is a matrix material and doped with a material such as Au, Pt, Pd, and Ir. Thus, great electromotive force has not been reported so far.

An object of the present invention is to provide a thermoelectric conversion element capable of achieving high-efficiency thermoelectric conversion by using a comparatively inexpensive material and an electromotive film to be used for such thermoelectric conversion element.

### Solution to Problem

The present invention is an electromotive film for a thermoelectric conversion element characterized by being a Ni-containing magnetic alloy wherein Ni is a matrix and doped with a 5d transition metal element.

Further, the present invention is a thermoelectric conversion element characterized by including: a magnetic material layer; an electromotive film formed on the magnetic material layer, the electromotive film being a Ni-containing magnetic alloy in which Ni is a matrix and doped with a 5d transition metal element and generating an electromotive force; and two terminal parts formed so as to be in contact with the electromotive film at two places where potentials due to the electromotive force are different.

### Advantageous Effects of the Invention

According to the present invention, it is possible to obtain a thermoelectric conversion element capable of obtaining high thermoelectric conversion efficiency with an inexpensive material compared with a system of precious metal materials such as Pt and Ir, and an electromotive film to be used for such thermoelectric conversion element.

### BRIEF DESCRIPTION OF THE DRAWINGS

FIG. 1 is a perspective view illustrating an electromotive film in a first example embodiment of the present invention;

FIG. 2 is a perspective view illustrating a thermoelectric conversion element in a second example embodiment of the present invention;

FIG. 3 is a perspective view illustrating a thermoelectric conversion element in a first example of the present invention;

FIG. 4 is a diagram in which thermoelectric performance (dependence of temperature difference ΔT on thermoelectromotive force V) of a film of a Ni₉₇W₃/Bi:YIG element formed on a SGGG substrate in the first example of the present invention is compared with performance of a Ni₉₀W₁₀/Bi:YIG element, a Ni/Bi:YIG element, and a Pt/Bi:YIG element;

FIG. 5 is a diagram in which thermoelectric performance (dependence of temperature difference ΔT on thermoelectromotive force V) of a film of a Ni₉₇W₃/Bi:YIG element formed on the SGGG substrate in the first example of the present invention is compared with thermoelectric performance of Nernst thermoelectric elements (Ni₉₇W₃, Ni) each obtained by directly forming a Ni-based magnetic film on a substrate;

FIG. 6 is a diagram illustrating a dependence of a doping amount x of W on thermoelectric conversion performance V/ΔT of a Ni₁₀₀₋ₓWₓ/Bi:YIG element;

FIG. 7 is a diagram illustrating a dependence of the doping amount x of W on the thermoelectric conversion performance V/ΔT of a Ni₁₀₀₋ₓWₓ element;

FIG. 8 is a diagram in which thermoelectric performance (dependence of temperature difference ΔT on thermoelectromotive force V) of a film of a Ni₉₇Pt₃/Bi:YIG element formed on the SGGG substrate in the first example of the present invention is compared with thermoelectric performance of a Pt/Bi:YIG element;

FIG. 9 is a diagram illustrating a dependence of a doping amount x of Pt on the thermoelectric conversion performance V/ΔT of a Ni₁₀₀₋ₓPtₓ/Bi:YIG element;

FIG. 10 is a diagram illustrating a dependence of the doping amount x of Pt on the thermoelectric conversion performance V/ΔT of a Ni₁₀₀₋ₓPtₓ element;

FIG. 11 is a diagram illustrating a dependence of a doping amount x of Au on the thermoelectric conversion performance V/ΔT of a Ni₁₀₀₋ₓAuₓ/Bi:YIG element;

FIG. 12 is a diagram illustrating a dependence of the doping amount x of Au on the thermoelectric conversion performance V/ΔT of a Ni₁₀₀₋ₓAuₓ element;

FIG. 13 is a perspective view illustrating a multilayer thermoelectric conversion element in a third example embodiment of the present invention; and

FIG. 14 is a perspective view illustrating a multilayer element in an example of the present invention.

### DESCRIPTION OF EMBODIMENTS

Hereinafter, example embodiments of the present invention will be described in detail with reference to drawings.

### First Example Embodiment

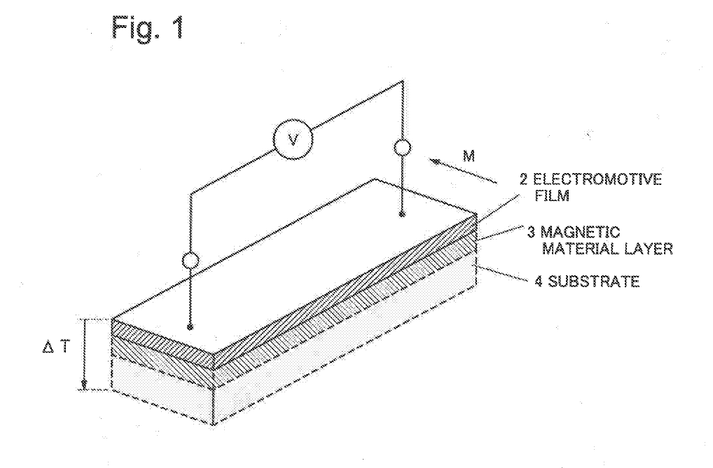

FIG. 1 is a perspective view illustrating an electromotive film 2 in an example embodiment of the present invention. To make it easy to understand, a magnetic material layer 3 located below the electromotive film 2 and a substrate 4 located below the magnetic material layer 3 are indicated by broken lines. The electromotive film 2 is a Ni-containing magnetic alloy in which Ni is a matrix and doped with a 5d transition metal element. An electromotive force V is induced under a temperature gradient. The 5d transition metal elements are Hf, Ta, W, Re, Os, Ir, Pt, and Au.

The inventors of the present invention have carried out research and development to increase thermoelectric conversion efficiency of a hybrid element using the spin Seebeck effect and the anomalous Nernst effect together. In the research and development, the inventors have found that a thermoelectric conversion element formed by combining a Ni-based alloy in which a Ni host is doped with 5d transition metal and a magnetic insulator to enable both the spin Seeback effect and the anomalous Nernst effect at the same time has a thermoelectric conversion effect higher than that of a typical spin Seebeck thermoelectric element. Further, the experiment has revealed that the thermoelectric conversion element using the Ni-based alloy in which the Ni host is doped with the 5d transition metal has thermoelectromotive force several times greater than that of a thermoelectric conversion element using a permalloy (Py), which is an alloy of Ni and Fe described in NPL 3. High thermoelectric conversion efficiency can be obtained with an inexpensive material compared with a system of precious metal materials such as Pt and Ir by using the electromotive film in the present example embodiment for the thermoelectric conversion element.

### Second Example Embodiment

First, a thermoelectric conversion element having a multilayer structure of a Ni-based alloy and a magnetic material layer (magnetic insulator or magnetic semiconductor layer) will be described as a second example embodiment of the present invention. In the thermoelectric conversion in the present example embodiment, the Ni-based alloy serves two functions. As one of the functions, the Ni-based alloy serves as a spin current-electric current conversion material that converts a spin current generated by the spin Seebeck effect from a temperature gradient in the magnetic material layer adjacent thereto and injected to the Ni-based alloy into an electric current by the inverse spin Hall effect, thereby generating electromotive force. As a second function, the Ni-based alloy serves as an electromotive material that directly generates electromotive force from a temperature gradient by the anomalous Nernst effect in the Ni-based alloy under the temperature gradient.

Note that a material having a composition in which a Ni host is doped with several % of a 5d transition metal material is used as the Ni-based alloy material herein.

In general, a material having large spin orbit coupling is desirable for efficient spin current-electric current conversion, but Ni, which is a comparatively light element, does not have very large spin orbit coupling. Further, a permalloy adopted as a magnetic metal material in NPL 3 contains Fe in addition to Ni. However, Fe is also a comparatively light element, and as a result, a Ni—Fe alloy like a permalloy exhibits not a very large spin current-electric current conversion effect.

On the other hand, in a case that the Ni is doped with a small amount of a 5d transition metal material having large spin orbit coupling, spin current-electric current conversion effectively progresses in a process in which a flow of electron spin is dispersed by a 5d transition metal atom in the Ni host. Thus, high-performance thermoelectric conversion can be achieved by using such an alloy material. In addition, since Ni is an inexpensive material compared with precious metal materials such as Pt and Ir, it is possible to obtain an element having high thermoelectric conversion efficiency at low cost.

It is desirable that more than or equal to 1 at % of the 5d transition metal is doped for efficient dispersion. On the other hand, in a case that the 5d transition metal material is excessively doped, the anomalous Nernst effect is reduced due to a decrease in magnetization of the Ni-based alloy, and thermoelectric conversion performance also conversely decreases. Therefore, the 5d transition metal is desirably less than or equal to 30 at %.

### Description of Element Structure

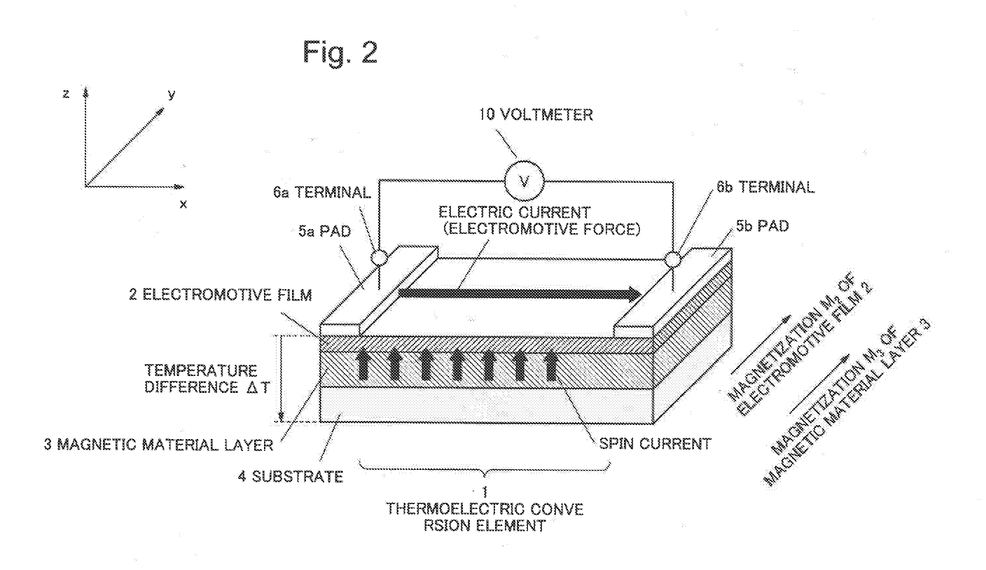

FIG. 2 is a perspective view of a thermoelectric conversion element 1 in a second example embodiment of the present invention. A magnetic material layer 3 is formed on a substrate 4, and an electromotive film 2 having electrical conductivity is further formed on the magnetic material layer 3, thereby forming the thermoelectric conversion element 1. In order to extract electromotive force, the thermoelectric conversion element 1 further includes pads 5a and 5b in contact with both end portions of the electromotive film 2 and terminals 6a and 6b in contact with the pads 5a and 5b, respectively.

The magnetic material layer 3 is a magnetic material that exhibits the spin Seebeck effect, has magnetization M₃ in one direction in a plane (in a direction from the front toward the back in the plane of paper), and generates (drives) a spin current Js from a temperature gradient ∇T (temperature difference ΔT) in a direction perpendicular to the plane by the spin Seebeck effect. A direction of the spin current Js is parallel or antiparallel to a direction of the temperature gradient ∇T. In the example illustrated in FIG. 2, the temperature gradient ∇T in −z direction is created, and the spin current Js along +z direction or −z direction is generated. In the present example embodiment, the substrate 4 side is at a high temperature while the electromotive film 2 side is at a low temperature, and an arrow indicates a direction from the low temperature toward the high temperature in FIG. 2. Further, the spin current refers to a flow of a vector called a spin. “A rightward spin flows in −Z direction” and “a leftward spin flows in +Z direction” indicate the same meaning. Therefore, even “a spin current in −Z direction” may reach the electromotive film.

Examples of a material for the magnetic material layer 3 include yttrium iron garnet (YIG, composition is Y₃Fe₅O₁₂), YIG doped with bismuth (Bi) (Bi:YIG, composition is BiY₂Fe₅O₁₂), Ni—Zn ferrite (composition is (Ni, Zn)ₓFe₃₋ₓO₄), and the like. Note that the magnetic material layer 3 desirably has small heat conductivity in terms of thermoelectric conversion efficiency, therefore, it is desirable to use a magnetic insulator which makes the electric current difficult to pass (makes an electron difficult to carry heat) therethrough.

Further, a ferromagnetic Ni-based alloy material is used as the electromotive film 2 in the present example embodiment, and the electromotive film 2 has magnetization M₂ in the same direction as that of M₃. This electromotive film 2 serves two following functions at the same time. As one of the functions, the electromotive film 2 performs spin current-electric current conversion that converts a spin current flowing thereinto by the spin Seebeck effect of the magnetic material layer 3 into electromotive force (electric field E_{SSE}) by the inverse spin Hall effect. As the other function, the electromotive film 2 directly generates electromotive force (electric field E_{ANE}) from a temperature gradient by the anomalous Nernst effect in the electromotive film 2.

Herein, a direction of the electric field E_{SSE} generated by the spin Seebeck effect is determined by a cross product of the direction of the magnetization M₃ of the magnetic material layer 3 and the direction of the temperature gradient ∇T (E_{SSE}∝M₃×∇T). Similarly, a direction of the electric field generated by the anomalous Nernst effect is determined by a cross product of the direction of the magnetization M₂ of the electromotive film 2 and the direction of the temperature gradient ∇T (E_{ANE}∝M₂×∇T). In addition, a sign of an actual electric field is also dependent on a material. However, in a case that an element configuration uses the electromotive film 2 in the present example embodiment, both of E_{SSE} and E_{ANE} are generated in the same direction with respect to a certain temperature gradient ∇T when the direction of the magnetization M₃ and the direction of the magnetization M₂ are the same direction. (In a case that the electric fields E_{SSE} and E_{ANE} are not in the same direction, electromotive force is generated in a direction resulting from vector addition of the electric fields E_{SSE} and E_{RNE}). Therefore, under such a condition, the two effects strengthen each other, and an absolute value of an electric field to be generated is |E_{Hybrid}|=|E_{SSE}|+|E_{ANE}|. In other words, electromotive force by the two effects is added. Note that as illustrated in FIG. 2, the directions of the magnetization M₃ of the magnetic material layer 3 and the magnetization M₂ of the electromotive film 2 are +y direction, the direction of the temperature gradient ∇T is −z direction, and the direction of the electromotive force is +x direction in the present example embodiment. Note that the direction of the electromotive force illustrated in FIG. 2 is a direction opposite to a direction expected from a usual cross product. Since the actual sign changes between +x and −x depending on a material for the electromotive film, FIG. 2 illustrates the direction from the terminal 6a toward the terminal 6b.

In the present example embodiment, a material in which Ni is a matrix material (where Ni is set at an atomic ratio of 90 at %) and is doped with a small amount of a 5d transition metal element having large spin orbit coupling is used as the electromotive film 2. As such a 5d transition metal material, W and Pt have high conversion efficiency. Therefore, W or Pt is desirably used, but other 5d transition metal materials such as Hf, Ta, Re, Os, Ir, and Au may also be used. In a case that Ni is doped with the 5d transition metal material having a great spin current-electric current conversion effect in such a manner, effective spin current-electric current conversion is generated when a flow of electron spin is dispersed by the 5d transition metal atom. As a result, high-efficiency thermoelectric conversion can be achieved.

More than or equal to 1 at % of a nonmagnetic 5d transition metal such as Pt and W is desirably doped for efficient dispersion. On the other hand, in a case that the 5d transition metal is excessively doped, the anomalous Nernst effect is reduced due to a decrease in magnetization of the Ni-based alloy, and performance of the thermoelectric conversion element using the two effects together as in the present example embodiment conversely decreases. Thus, the 5d transition metal is desirably less than or equal to 30 at %. Therefore, a doping amount of the 5d transition metal desirably falls within a range of 1 to 30 at % at an atomic ratio. Note that a film thickness of the electromotive film 2 is about a spin diffusion length (5 to 20 nm) of a used Ni-based alloy material, desirably less than or equal to 30 nm.

The pads 5a and 5b are provided in contact with both the end portions of the electromotive film 2 to effectively extract electromotive force from the electromotive film 2. As a material for the pads 5a and 5b, a metal material having a low resistance is desirable, and, for example, Au, Pt, Ta, Cu, and the like can be used. A film thickness of the pads 5a and 5b is desirably thicker than that of the electromotive film 2, desirably greater than or equal to 30 nm. A contact resistance between the electromotive film and the terminals 6a and 6b can be reduced by forming the pads 5a and 5b. Further, a resistance between the terminals is further reduced in an equivalent circuit is reduced more by sandwiching the electromotive film 2 between pads having a film thickness to some extent than by pinpoint placement of terminals on the thin electromotive film 2.

The electromotive force is eventually extracted between the two terminals 6a and 6b in contact with the pads 5a and 5b, respectively. For example, when an open-circuit voltage between the two terminals 6a and 6b is measured by a voltmeter 10 as illustrated in FIG. 2, magnitude of the electromotive force generated by the element can be evaluated.

Note that the pads 5a and 5b are not always necessary for providing the thermoelectric conversion function, and the terminals 6a and 6b may be directly formed on the electromotive film 2.

### Method for Making Thermoelectric Conversion Element

Next, a method for making the thermoelectric conversion element 1 according to the present example embodiment is described.

First, examples of a method for forming the magnetic material layer 3 include a method for forming a film by using any of methods such as a sputtering method, a metal organic deposition (MOD) method, a pulsed laser deposition (PLD) method, a sol-gel method, an aerosol deposition (AD) method, a ferrite plating method, and a liquid phase epitaxy (LPE) method. In this case, a film of the magnetic material layer 3 is formed on some sort of substrate.

As a method for forming the electromotive film 2, a reactive sputtering method in oxygen environment, the MOD method, or the like is used to form the film.

The pads 5a and 5b are formed by the sputtering method, a vacuum deposition method, an electron-beam evaporation method, a plating method, or the like.

### First Example

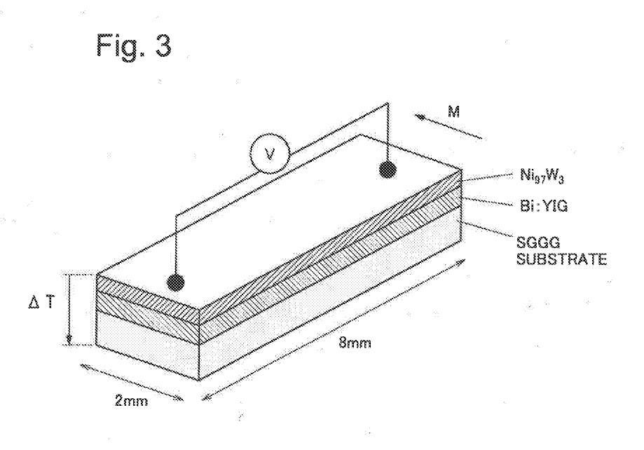

A thermoelectric conversion element was made and its effect was verified to verify an effect of the present invention. As illustrated in FIG. 3, a nickel-tungsten alloy Ni₉₇W₃ was used as the electromotive film 2 in the present example embodiment.

A BiY₂Fe₅O₁₂ (Bi:YIG) magnetic film having a film thickness of 120 nm was formed on a (GdCa)₃(GaMgZr)₅O₁₂ (hereinafter referred to as SGGG (abbreviation of substituted gadolinium gallium garnet)) substrate having a thickness of 0.5 mm. Furthermore, a Ni-based alloy film Ni₉₇W₃ having a film thickness of 10 nm was formed on the Bi:YIG magnetic film to serve as an electromotive film, thereby making the thermoelectric conversion element. Herein, the metal organic decomposition method (MOD method) being a method for forming a film of a coating base was used for forming the YIG magnetic film. In this method, a solution with an organic metal containing Y and Fe dissolved therein (MOD solution) was coated by spin coating (a number of revolutions is 1000 rpm) and was annealed at 700° C., thereby forming the YIG.

Herein, the Ni₉₇W₃ was formed by a magnetron sputtering method using a sintered Ni₉₇W₃ alloy target.

Elements using platinum (Pt) and Ni, which are currently adopted as an electromotive film for spin Seebeck element in general, were prepared at the same time to compare with performance of the thermoelectric conversion element. Also in a case of these elements, after a film of the Bi:YIG magnetic film having a film thickness of 120 nm was formed on the SGGG substrate by the same above-described method, Pt having a film thickness of 10 nm was formed on the Bi:YIG magnetic film by sputtering method, thereby making the comparison elements.

Next, a thermoelectric characteristic evaluation of the hybrid spin thermoelectric element (Ni₉₇W₃/Bi:YIG/SGGG substrate) that had been made is described. Herein, a sample of the wafer made by the above-described method and cut out into 8×2 mm was used. A temperature difference ΔT in the direction perpendicular to the plane was created between an upper end and a lower end while the Bi:YIG magnetic film was magnetized in a short-side direction of the Ni₉₇W₃ film. Thereby, electromotive force (output voltage) generated by addition of the spin Seebeck effect (SSE) and the anomalous Nernst effect in a long-side direction of the Ni₉₇W₃ film was measured.

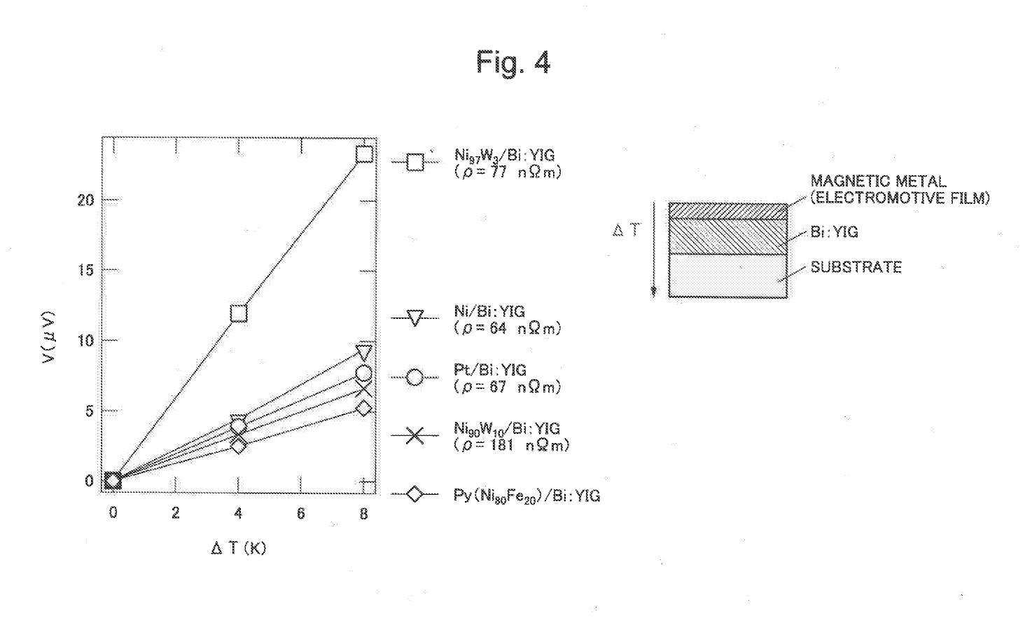

FIG. 4 illustrates a thermoelectric characteristic of the hybrid spin thermoelectric element (Ni₉₇W₃/Bi:YIG) using the SSE and the ANE together in comparison with a standard spin thermoelectric element (Pt/Bi:YIG) having only the SSE under the same condition including the film thickness, a hybrid spin thermoelectric element (Py/Bi:YIG) using a permalloy Py (Ni₈₀Fe₂₀), and the like. The thermoelectric conversion performance of the hybrid element was V/ΔT=2.9 μV/K, which indicated about three times greater electromotive force performance than that of the normal spin thermoelectric element Pt/Bi:YIG. A resistance of Ni₉₇W₃ evaluated in the 4-terminal measurement was ρ=77nΩm, which was slightly greater than Pt (ρ=64nΩm). Further, it also indicated that the Ni₉₇W₃/Bi:YIG element had thermoelectromotive force performance about four times greater than that of the hybrid spin thermoelectric element (Py/Bi:YIG) using Py and having the same configuration as that of NPL 3.

FIG. 4 also illustrates an evaluation result of an Ni/Bi:YIG element using Ni as a metal film at the same time. The Ni₉₇W₃/Bi:YIG element had thermoelectromotive force performance two times or more greater than that of the Ni/Bi:YIG element. It was inferred that W doped in the Ni host effectively dispersed a spin current to cause an increase in spin current-electromotive force conversion. However, the performance of the Ni₉₀W₁₀/Bi:YIG element was conversely reduced when a doping amount of W was further increased (FIG. 4), and it was confirmed that the doping amount of W had an appropriate range.

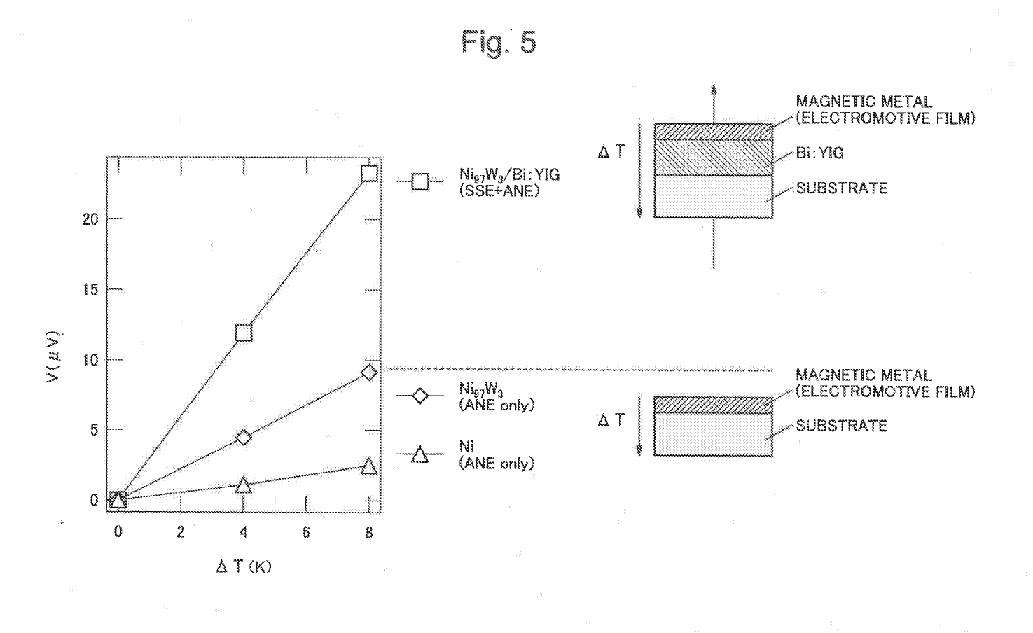

Further, FIG. 5 illustrates an evaluation result of electromotive force of the same Ni₉₇W₃/Bi:YIG element in comparison with thermoelectric performance of elements obtained by forming films of Ni₉₇W₃ and Ni directly on a substrate without using a magnetic insulating film (Bi:YIG). It was indicated that greater electromotive force was obtained in the Ni₉₇W₃/Bi:YIG element in which an SSE signal is added to the ANE and contributes to an output voltage together with the ANE than that in the Ni₉₇W₃ element and the Ni element in which only the ANE contributes to the signal.

### Second Example

With the result of the first example, in order to determine an optimum doping amount of W, thermoelectric conversion elements were made by using Ni₁₀₀₋ₓWₓ as an electromotive film, whose doping ratios x (at %) of W varied incrementally, and a dependence of a composition on thermoelectric conversion performance was examined.

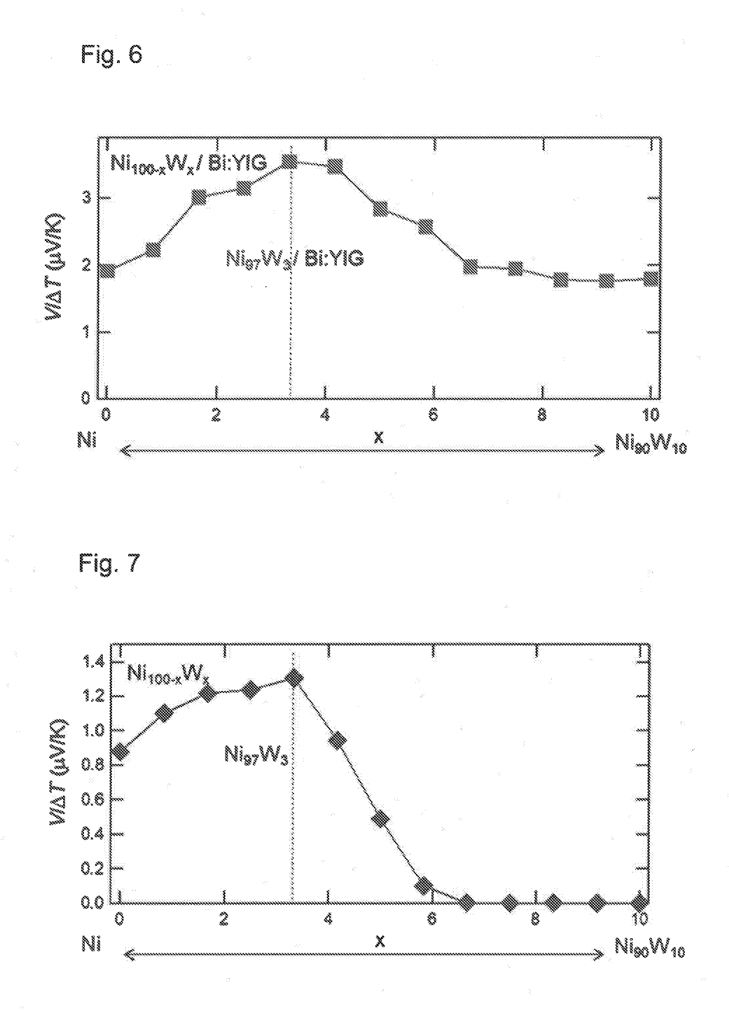

A hybrid spin thermoelectric element in the present example used the SGGG substrate as in the first example. After a Bi:YIG film having a film thickness of 120 nm was formed on the substrate also by the MOD method, a N₁₀₀₋ₓWₓ film having a film thickness of 10 nm was formed by the sputtering method. FIG. 6 illustrates a dependence of a doping amount x of W on thermoelectric conversion performance V/ΔT. The thermoelectric performance was dependent on x, and an improvement in the performance by doping W was seen. However, the performance conversely decreased after x exceeded a certain amount. From this experiment, an optimum value of x was 3 (at %), and a doping ratio x that produces an effect of significantly improving performance by doping W is desirably greater than or equal to 1 (at %) and less than or equal to 5 (at %).

In addition, an element obtained by directly forming the Ni₁₀₀₋ₓWₓ film on the SGGG was also made and evaluated. The spin Seebeck effect did not appear in the element, and only the anomalous Nernst effect contributed to a thermoelectric signal. FIG. 7 illustrates a dependence of the doping amount x of W on the thermoelectric conversion performance V/ΔT of the anomalous Nernst element. A signal was smaller than that in the hybrid spin thermoelectric element, but the signal became the greatest at x=3 (at %) nevertheless.

### Third Example

A thermoelectric conversion element was made and its effect was verified to verify an effect of the present invention. A nickel-platinum alloy Ni₉₇Pt₃ was used as the electromotive film 2 as illustrated in FIG. 3 in the present example.

By also using the same producing process as in the first example herein, a BiY₂Fe₅O₁₂ (Bi:YIG) magnetic film having a film thickness of 120 nm was formed on a substrate. Then, a Ni-based alloy film Ni₉₇Pt₃ having a film thickness of 10 nm was further formed on the Bi:YIG magnetic film, thereby making the element. The Ni₉₇Pt₃ was formed by the magnetron sputtering method using a sintered Ni₉₇Pt₃ alloy target.

An element using platinum (Pt), which is currently adopted as an electromotive film for spin Seebeck element in general, was prepared at the same time to compare with performance of the thermoelectric conversion element. Also in a case of these elements, after a film of the Bi:YIG magnetic film having a film thickness of 120 nm was formed on the SGGG substrate by the same above-described method, Pt having a film thickness of 10 nm was formed on the Bi:YIG magnetic film by the sputtering method, thereby making a comparison element.

A wafer made by the above-described reactive sputtering method was cut into a sample of 2×8 mm, and its thermoelectric characteristic was evaluated while a temperature gradient was created from the electromotive film toward the magnetic film as illustrated in FIG. 3. In a case that the temperature difference ΔT was created in a thickness (perpendicular to the plane) direction of the element including the substrate in such a manner, an electromotive force V was generated in an in-plane direction orthogonal to each of the direction of the temperature gradient and the direction of the magnetization M of the magnetic film.

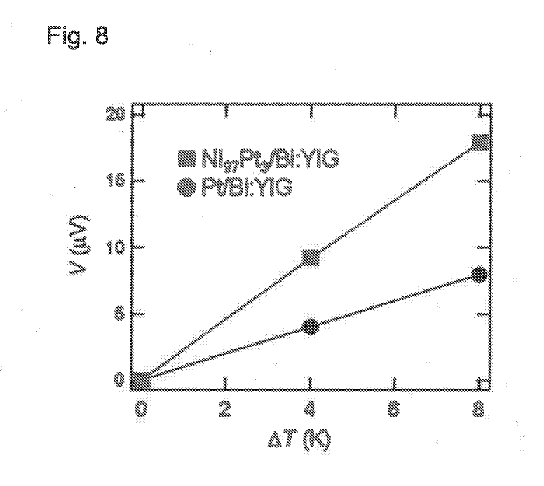

FIG. 8 illustrates a dependence of the temperature difference ΔT on the thermoelectromotive force V of a Ni₉₇Pt₃/Bi:YIG/SGGG in comparison with a Pt/Bi:YIG/SGGG element. An absolute value of a thermoelectric coefficient of an element in the present third example using the Ni₉₇Pt₃ was 2.2 μV/K, which indicated a value about 2.2 times greater than that in a case of Pt.

As described above, although an output was smaller than that of the Ni₉₇W₃ electromotive film (first example), it was demonstrated that a thermoelectric conversion output voltage greater than that of Pt being a precious metal can be obtained by the combination of the anomalous Nernst effect and the spin Seebeck effect even in a case that the Ni₉₇Pt₃ was used as the electromotive film.

### Fourth Example

With the result of the third example, in order to determine an optimum doping amount of Pt, thermoelectric conversion elements were made by using Ni₁₀₀₋ₓPtₓ as an electromotive film, whose doping ratios x (at %) of Pt varied incrementally, and a dependence of a composition on thermoelectric conversion performance was examined.

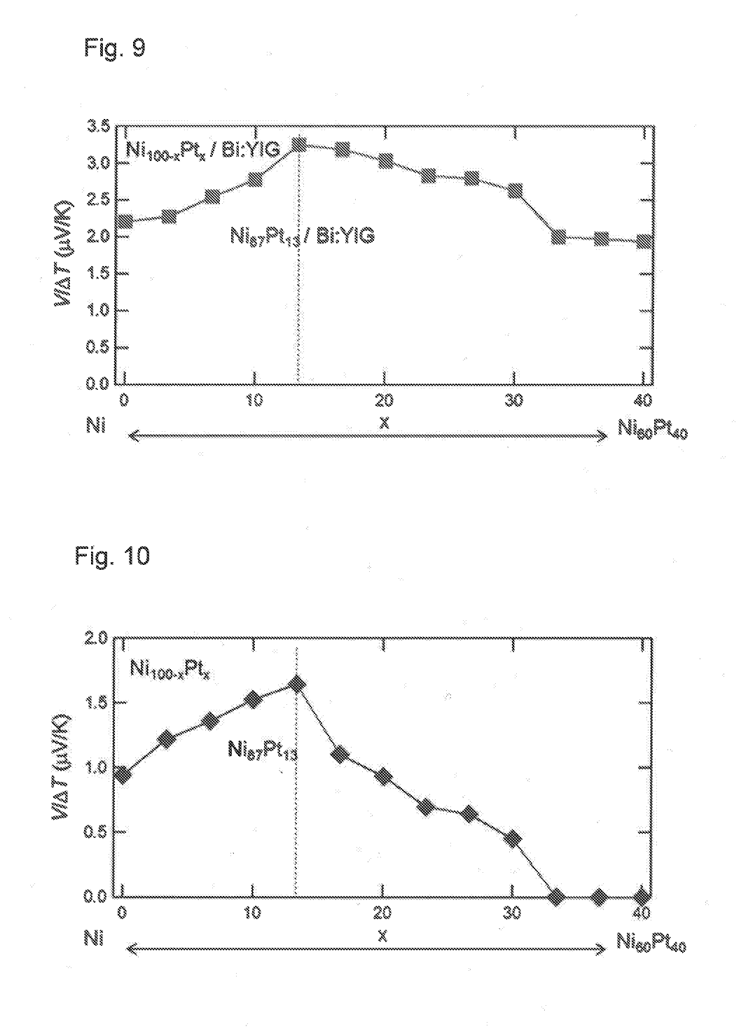

A hybrid spin thermoelectric element in the present example used the SGGG substrate as in the first example. After a Bi:YIG film having a film thickness of 120 nm was formed on the substrate also by the MOD method, a film of a N₁₀₀₋ₓPtₓ film having a film thickness of 10 nm was formed by the sputtering method. FIG. 9 illustrates a dependence of the doping amount x of Pt on the thermoelectric conversion performance V/ΔT. The thermoelectric performance was dependent on x, and an improvement in the performance by doping Pt was seen. However, the performance conversely decreased after x exceeded a certain amount. From this experiment, an optimum value of x was 13 (at %), and a doping ratio x that produces an effect of significantly improving performance by doping Pt is desirably greater than or equal to 3 (at %) and less than or equal to 30 (at %).

An element obtained by directly forming the Ni₁₀₀₋ₓPtₓ film on the SGGG was also made and evaluated. The spin Seebeck effect did not appear in the element, and only the anomalous Nernst effect contributed to a thermoelectric signal. FIG. 10 illustrates a dependence of the doping amount x of Pt on the thermoelectric conversion performance V/ΔT of the anomalous Nernst element. A signal was smaller than that in the hybrid spin thermoelectric element, but the signal became the greatest at x=13 (at %) nevertheless.

### Fifth Example

In the present fifth example, an element using a nickel-platinum alloy as the electromotive film 2 as illustrated in FIG. 3 was also prototyped and evaluated. In order to determine an optimum doping amount of Au, thermoelectric conversion elements were made by using N₁₀₀₋ₓAuₓ as an electromotive film, whose doping ratios x (at %) of Au varied incrementally, and a dependence of a composition on thermoelectric conversion performance was examined.

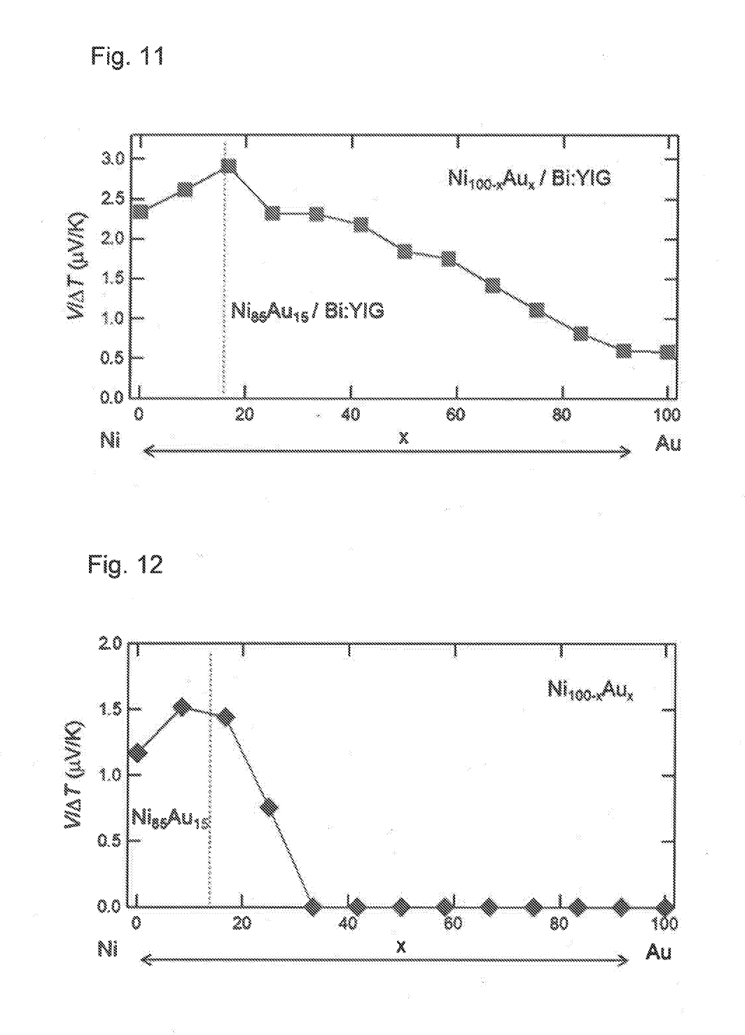

A hybrid spin thermoelectric element in the present example used the SGGG substrate as in the first example. After a Bi:YIG film having a film thickness of 120 nm was formed on the substrate also by the MOD method, a film of a Ni₁₀₀₋ₓAuₓ film having a film thickness of 10 nm was formed by the sputtering method. FIG. 11 illustrates a dependence of a doping amount x of Au on the thermoelectric conversion performance V/ΔT. The thermoelectric performance was dependent on x, and an improvement in the performance by doping Au was seen. However, the performance conversely decreased after x exceeded a certain amount. From this experiment, an optimum value of x was 15 (at %), and a doping ratio x that produces an effect of significantly improving performance by doping Au is desirably greater than or equal to 3 (at %) and less than or equal to 25 (at %).

Further, an element obtained by directly forming the Ni₁₀₀₋ₓAuₓ film on the SGGG was also made and evaluated. The spin Seebeck effect did not appear in the element, and only the anomalous Nernst effect contributed to a thermoelectric signal. FIG. 12 illustrates a dependence of the doping amount x of Au on the thermoelectric conversion performance V/ΔT of the anomalous Nernst element. A signal was smaller than that in the hybrid spin thermoelectric element, but the signal became the greatest around x=15 (at %) nevertheless.

### Third Example Embodiment

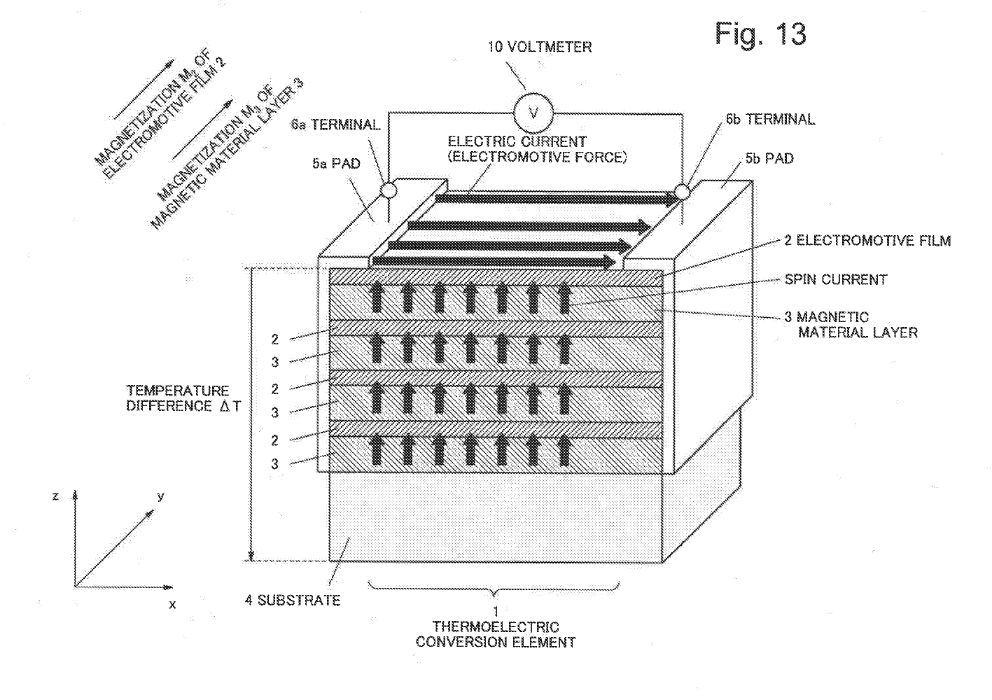

Next, a multilayer thermoelectric conversion element in which an electromotive film 2 and a magnetic material layer 3 are stacked alternately will be described as a third example embodiment of the present invention. FIG. 13 illustrates a perspective view of a multilayer thermoelectric conversion element.

In a thermoelectric conversion element 1, the magnetic material layer 3 and the electromotive film 2 are stacked alternately in a plurality of layers on a substrate 4. In FIG. 13, the magnetic layers and the electromotive films are stacked in total of four layers. In order to extract electromotive force, pads 5a and 5b in contact with all of the plurality of electromotive films 2 are formed, and terminals 6a and 6b in contact with the pads 5a and 5b, respectively, are further formed.

Also in the present example embodiment, a ferromagnetic Ni-based alloy material is used as the electromotive film 2 as in the first example embodiment. Further, each of the electromotive films 2 and the magnetic material layers 3 has a magnetization M₂ and a magnetization M₃ in the same direction, that is to say, an in-plane direction from the front toward the back in the plane of paper.

Each of the plurality of magnetic material layers 3 is a magnetic material that exhibits the spin Seebeck effect as in the second example embodiment and generates (drives) a spin current Js in each of the magnetic material layers 3 under a temperature gradient ∇T (temperature difference ΔT) in the direction perpendicular to the plane. Examples of a material for the magnetic material layer 3 include yttrium iron garnet (YIG, composition is Y₃Fe₅O₁₂), YIG doped with bismuth (Bi) (Bi:YIG, composition is BiY₂Fe₅O₁₂), Ni—Zn ferrite (composition is (Ni, Zn)ₓFe₃₋ₓO₄), and the like. Note that the magnetic material layer 3 desirably has small heat conductivity in terms of thermoelectric conversion efficiency, therefore, it is desirable to use a magnetic insulator which makes the electric current difficult to pass (makes an electron difficult to carry heat) therethrough.

The spin current generated in each of the magnetic material layers 3 flows to the electromotive films 2 in contact with the top and the bottom of the magnetic material layer 3, and then the spin current is converted into electromotive force (electric field E_{SSE}) by the inverse spin Hall effect. Note that the electromotive film 2 sandwiched between the magnetic material layers 3 receives a contribution of the spin current from the upper and lower magnetic material layers 3 in this configuration. Thereby, as a result, the amount of spin current flowing in the electromotive film 2 and the electromotive force are nearly doubled in comparison with those in the first example embodiment.

Further, also in the present example embodiment, Nernst electromotive force (electric field E_{ANE}) is also directly generated from a temperature gradient by the anomalous Nernst effect in the electromotive film 2. As in the second example embodiment, the two effects also strengthen each other, and a larger electromotive force is obtained in the present example embodiment.

The effect of the present example embodiment is that it is possible to obtain greater thermoelectromotive force than the element in the second example embodiment. In addition, there is an effect that an internal resistance of an element can be reduced, and greater power can be extracted because a plurality of Ni-based alloy films 2 are electrically connected in parallel.

Note that only one kind of the 5d transition metal is doped in the first and second example embodiments, but plural kinds such as W and Pt can be doped.

### Example of Present Example Embodiment

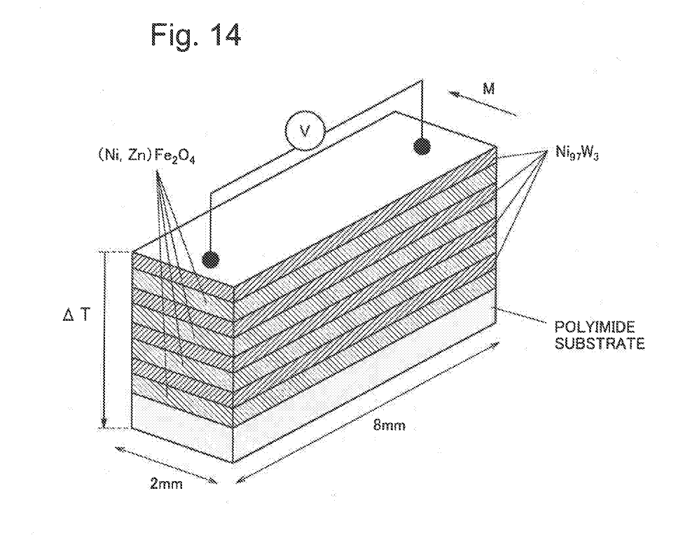

Next, a specific example of the thermoelectric conversion element of the present invention is described with reference to FIG. 14.

In the present example, a polyimide substrate having a thickness of 25 μm, (Ni, Zn)Fe₂O₄ having a thickness of 1 μm, and Ni₉₇W₃ having a film thickness of 10 nm were respectively adopted as the substrate 4, the magnetic material layer 3, and the electromotive film 2.

In the present example, (Ni, Zn)Fe₂O₄ having a film thickness of 3 μm was formed on the polyimide substrate by using the ferrite plating method. In the ferrite plating method, (i) a metal hydroxide ion was adsorbed by bringing an aqueous solution containing Ni²⁺, Zn²⁺, and Fe²⁺ ions and the like into contact with a polyimide surface. Subsequently, (ii) they were oxidized by an oxidizing agent (Fe²⁺→Fe³⁺), and (iii) this was further caused to react with the metal hydroxide ion in the aqueous solution to crystallize ferrite, thereby forming a ferrite film on the substrate surface. A ferrite film (Ni, Zn)Fe₂O₄ having a film thickness of 1 μm was formed by successively repeating the steps of (i) to (iii). Furthermore, a film of Ni₉₇W₃ having a film thickness of 10 nm was formed as a Ni-based alloy film 3 on the upper surface of the ferrite film by the sputtering method.

Forming a film of ferrite by the ferrite plating method and forming a film of Ni₉₇W₃ by the sputtering method were repeated for four times, thereby making a multilayer element illustrated in FIG. 14.

As a result of evaluating a thermoelectric characteristic of the element that had been made, there was obtained electromotive force performance of V/ΔT=4.6 μV/K, which is about 1.6 times greater than that of the element illustrated in the first example in the second example embodiment. In addition, an internal resistance (resistance between terminals) was about a quarter of that of the element in the first example embodiment.

The present invention has been described above by taking the above-mentioned example embodiments as exemplary examples. However, the present invention is not limited to the above-mentioned example embodiments. In other words, various aspects apparent to those skilled in the art may be applied to the present invention within the scope of the present invention.

This application is based upon and claims the benefit of priority from Japanese patent application No. 2015-223201, filed on Nov. 13, 2015 and Japanese patent application No. 2016-161325, filed on Aug. 19, 2016, the disclosure of which is incorporated herein in its entirety by reference.

### REFERENCE SIGNS LIST

1 Thermoelectric conversion element
2 Electromotive film
3 Magnetic material layer
4 Substrate
5a, 5b Pad
6a, 6b Terminal
10 Voltmeter

1. An electromotive film for a thermoelectric conversion element that induces an electromotive force under a temperature gradient,
the electromotive film being a Ni-containing magnetic alloy wherein Ni is a matrix and doped with a 5d transition metal element.

2. The electromotive film for a thermoelectric conversion element according to claim 1, wherein
a doping amount of the 5d transition metal element is 1 to 30 at % in atomic ratio.

3. The electromotive film for a thermoelectric conversion element according to claim 1, wherein
the 5d transition metal element is W, Pt, or Au.

4. A thermoelectric conversion element comprising:
a magnetic material layer;
an electromotive film formed on the magnetic material layer, the electromotive film being a Ni-containing magnetic alloy, in which Ni is a matrix and doped with a 5d transition metal element, and generating an electromotive force; and
two terminal parts formed so as to be in contact with the electromotive film at two places where potentials due to the electromotive force are different.

5. The thermoelectric conversion element according to claim 4, wherein
the electromotive film generates the electromotive force in an in-plane direction by inverse spin Hall effect and anomalous Nernst effect.

6. The thermoelectric conversion element according to claim 4, wherein
the electromotive film and the magnetic material layer are stacked alternately in a plurality of layers.

7. The thermoelectric conversion element according to claim 4, wherein
the magnetic material layer and the electromotive film have magnetization in a same direction.

8. The thermoelectric conversion element according to claim 4, further comprising
metal pads, each metal pad being electrically in contact with both the electromotive film and the terminal part.

9. The thermoelectric conversion element according to claim 4, wherein
the electromotive film has a film thickness of less than or equal to 30 nm.

10. The thermoelectric conversion element according to claim 4, wherein
the magnetic material layer is a magnetic insulator.
